(19) United States
(12) Patent Application Publication
(10) Pub. No.: US 2024/0194441 A1
(43) Pub. Date: Jun. 13, 2024

(54) POWER ADJUSTMENT METHOD OF UPPER ELECTRODE POWER SUPPLY AND SEMICONDUCTOR PROCESS APPARATUS

(71) Applicant: BEIJING NAURA MICROELECTRONICS EQUIPMENT CO., LTD., Beijing (CN)

(72) Inventors: Jing WEI, Beijing (CN); Yu ZHANG, Beijing (CN); Gang WEI, Beijing (CN); Jing YANG, Beijing (CN); Guibin WANG, Beijing (CN); Xin YUE, Beijing (CN)

(21) Appl. No.: 18/553,561

(22) PCT Filed: Mar. 16, 2022
(86) PCT No.: PCT/CN2022/081077

§ 371 Date: Sep. 30, 2023

(30) Foreign Application Priority Data
Apr. 1, 2021 (CN) 202110356810.0

(51) Int. Cl. H01J 37/244; H01J 37/32

(52) U.S. Cl. CPC H01J 37/244; H01J 37/32568; H01J 37/32899; H01J 2237/24564; H01J 2237/2485; H01J 2237/334

(57) ABSTRACT

The present disclosure provides a power adjustment method of an upper electrode power supply of a semiconductor process apparatus. The method includes obtaining a processing load of an upper electrode power supply of a reference process chamber and a processing load of an upper electrode power supply of a current process chamber corresponding to semiconductor process step, when starting to perform a semiconductor process step, determining a power compensation coefficient for the current process chamber relative to the reference process chamber based on the processing load of the current process chamber and the processing load the reference process chamber, and controlling the upper electrode power supply to output compensation power. The compensation power is a product of the set power of the upper electrode power supply of the current process chamber corresponding to the semiconductor process step and the corresponding power compensation coefficient. With the power adjustment method of the present disclosure, the consistency of the plasma parameters in different process chambers is improved, thereby improving the process result consistency. The present disclosure also provides the semiconductor process apparatus.

### TECHNICAL FIELD

The present disclosure generally relates to the semiconductor process field and, more particularly, to a power adjustment method of an upper electrode power supply and a semiconductor process apparatus.

### BACKGROUND

With the rapid development of semiconductor device manufacturing processes, requirements for device performance and integration have become higher and higher. Plasma technology has been widely used. In a plasma etching or deposition system, by introducing various reaction gases (such as Cl₂, SF₆, C₄F₈, O₂, etc.) into a vacuum process chamber, bound electrons in a gas atom are freed from potential wells by applying an external electromagnetic field (DC or AC). Then, free electrons with kinetic energy collide with molecules, atoms, or ions to completely deionize the gases to form the plasma. The plasma includes a large number of active particles such as electrons, ions (including positive and negative ions), excited-state atoms, molecules, and radicals. These active particles interact with a wafer surface placed in the chamber and exposed to the plasma, which causes various physical and chemical reactions on the wafer surface to change the performance of the material surface to complete the etching or another process processing. In developing the plasma apparatus for the semiconductor manufacturing process, a most important factor is to improve the processing capability on the substrate to improve productivity and the capability to manufacture highly integrated devices.

As the feature size of integrated circuits continues to shrink, the required processing processes become increasingly stringent. One important requirement is etching product consistency. In the processing process, a strict requirement needs to be imposed on the process result consistency of all chambers of machines of a same model number. Thus, different chambers need to be controlled through a strict process to realize the process result consistency.

However, in the existing semiconductor process apparatus, state parameters such as plasma density generated in a plurality of process chambers of a plurality of machines are often different, and the process result consistency is poor.

### SUMMARY

The present disclosure aims to provide a method for adjusting the power of an upper electrode power supply and a semiconductor process apparatus. The power adjustment method can improve the consistency of plasma parameters in different process chambers, thereby enhancing the consistency of process results.

To realize the above purpose, an aspect of the present disclosure provides a power adjustment method of an upper electrode power supply of a semiconductor process apparatus, including:
obtaining a processing load of an upper electrode power supply of a reference process chamber and a processing load of an upper electrode power supply of a current process chamber corresponding to a semiconductor process step;
when starting to perform the semiconductor process step, determining a power compensation coefficient for the current process chamber relative to the reference process chamber according to the processing load of the current process chamber and the processing load of the reference process chamber corresponding to the semiconductor process step; and
controlling the upper electrode power supply of the current process chamber to output a compensation power, the compensation power being a product of a set power of the upper electrode power supply of the current process chamber corresponding to the semiconductor process step and the corresponding power compensation coefficient.

In some embodiments, determining the power compensation coefficient for the current process chamber relative to the reference process chamber according to the processing load of the current process chamber and the processing load of the reference process chamber includes:
calculating a ratio between the processing load of the current process chamber and the processing load of the reference process chamber and using the ratio as the power compensation coefficient.

In some embodiments, upper electrode circuits are arranged at the reference process chamber and the current process chamber, the upper electrode power supply is configured to output power to the corresponding process chamber through a corresponding upper electrode circuit, and obtaining the processing load of the upper electrode power supply of the reference process chamber and the processing load of the upper electrode power supply of the current process chamber corresponding to the semiconductor process step includes:
obtaining a plasma load of the reference process chamber corresponding to the semiconductor process step;
adding the circuit load of the reference process chamber and the plasma load to obtain the processing load of the reference process chamber; and
adding the circuit load of the current process chamber and the plasma load of the reference process chamber to obtain the processing load of the current process chamber.

In some embodiments, obtaining the plasma load of the reference process chamber corresponding to the semiconductor process step includes:
when performing the semiconductor process step, controlling the upper electrode power supply of the reference process chamber to output a processing power and detecting a process current between the upper electrode power supply and the reference process chamber;
obtaining the processing load of the reference process chamber according to the processing power and the process current; and
subtracting the circuit load of the reference process chamber from the processing load of the reference process chamber to obtain the plasma load of the reference process chamber.

In some embodiments, obtaining the processing load of the reference process chamber according to the processing power and the process current includes:
calculating a ratio of the processing power to square of the process current and using the ratio as the processing load.

In some embodiments, the circuit load of any one of the reference process chamber and the current process chamber is obtained by:
controlling the upper electrode power supply of the process chamber to output detection power to detect a detection current between the upper electrode power supply ad the process chamber, the plasma being not ignited in the process chamber under the detection power; and
obtaining the circuit load of the process chamber according to the detection power and detection current of the process chamber.

In some embodiments, obtaining the circuit load of the process chamber according to the detection power and detection current of the process chamber includes:
calculating a ratio of the detection power to square of the detection current and using the ratio as the circuit load.

The power control method according to claim 3, wherein a plurality of semiconductor process steps are provided.

After obtaining the processing load of the upper electrode power supply of the reference process chamber and the processing load of the upper electrode power supply of the current process chamber corresponding to the semiconductor process step, and before starting to perform all the semiconductor process steps, the method further includes:
writing the obtained plasma load of the reference process chamber corresponding to each semiconductor process step of the plurality of semiconductor process steps into a parameter table;
accessing the circuit load of the reference process chamber and the circuit load of the current process chamber;
when starting to perform the semiconductor process step, determining the power compensation coefficient of the current process chamber relative to the reference process chamber corresponding to the semiconductor process step according to the processing load of the current process chamber and the processing load of the reference process chamber including:
   when starting to perform the semiconductor process steps, accessing the plasma load of the reference process chamber corresponding to a current semiconductor process step in the parameter table; and
   determining the power compensation coefficient of the current process chamber relative to the reference process chamber corresponding to the current semiconductor process step according to the processing load of the current process chamber and the processing load of the reference process chamber.

A second aspect of the present disclosure provides a semiconductor process apparatus comprising a plurality of process chambers, wherein the semiconductor process apparatus is configured to adjust power of upper electrode power supplies of the plurality of process chambers through the power adjustment method of the upper electrode power supply of embodiments of the present disclosure. Any one process chamber of the plurality of process chambers are used as the reference process chamber, and a process chamber of the other process chambers that performs the semiconductor process step is the current process chamber.

The semiconductor process apparatus further includes:
an acquisition unit configured to obtain the processing load of the upper electrode power supply of the reference process chamber and the processing load of the upper electrode power supply of the current process chamber corresponding to the semiconductor process step;
a calculation unit configured to determine the power compensation coefficient for the current process chamber relative to the reference process chamber corresponding to the semiconductor process step according to the processing load of the current process chamber and the processing load of the reference process chamber; and
a control unit configured to, when performing the semiconductor process step, control the upper electrode power supply of the current process chamber to output the compensation power, the compensation power being the product of the set power of the upper electrode power supply of the current process chamber corresponding to the semiconductor process step and the corresponding power compensation coefficient.

In some embodiments, the acquisition unit includes a plurality of current detection devices. A number of the current detection devices is the same as a number of the process chambers. The current detection devices are arranged between the electrode power supplies and the corresponding process chambers in a one-to-one correspondence. The current detection devices are configured to obtain the process current and/or the detection current between the corresponding upper electrode power supplies and the corresponding process chambers, and the detection current refers to a current outputted by the upper electrode power supply when the plasma is not ignited in the process chamber.

With the power adjustment method and the semiconductor process apparatus of embodiments of the present disclosure, the power compensation coefficient of the current process chamber relative to the reference process chamber can be obtained according to the processing load of the upper electrode power supply of the reference process chamber and the processing load of the upper electrode power supply of the current process chamber corresponding to the semiconductor process step. The upper electrode power supply of the current process chamber can be controlled to output the compensation power. The compensation power can be the product of the set power of the upper electrode power supply of the current process chamber corresponding to the semiconductor process step and the corresponding power compensation coefficient. Thus, the power applied to the plasma in the current process chamber can remain consistent with the power applied to the plasma in the reference process chamber to improve the parameter consistency of the plasma in different process chambers to further improve the process result consistency.

### BRIEF DESCRIPTION OF THE DRAWINGS

The accompanying drawings are provided to further understand embodiments of the present disclosure and form a part of the specification. The accompanying drawings are used to explain the present disclosure with the following detailed embodiments but do not limit the scope of the present disclosure. In the drawings:

FIG. 1 illustrates a schematic structural diagram of an existing semiconductor process apparatus.

FIG. 2 illustrates a schematic diagram showing a power loss of an upper electrode radio frequency circuit of the semiconductor process apparatus in FIG. 1.

FIG. 3 illustrates a schematic diagram showing an equivalent circuit of the upper electrode radio frequency circuit of the semiconductor process apparatus in FIG. 1.

FIG. 4 illustrates a schematic structural diagram after transformation of the equivalent circuit in FIG. 3.

FIG. 5 illustrates a partial schematic structural diagram showing a semiconductor process apparatus according to an embodiment of the present disclosure.

FIG. 6 illustrates a schematic diagram showing an equivalent circuit of an upper electrode radio frequency circuit of a process chamber of a semiconductor process apparatus according to an embodiment of the present disclosure.

FIG. 7 illustrates a schematic diagram showing an equivalent circuit when a semiconductor process step is performed in a process chamber of a semiconductor process apparatus according to an embodiment of the present disclosure.

FIG. 8 illustrates a schematic diagram showing an equivalent circuit when another semiconductor process step is performed in a process chamber of a semiconductor process apparatus according to an embodiment of the present disclosure.

FIG. 9 illustrates a schematic principle diagram showing obtaining processing loads of different process chambers and process compensation coefficients in the power adjustment method of a power supply of an upper electrode of a semiconductor process apparatus according to an embodiment of the present disclosure.

FIG. 10 illustrates a schematic diagram showing a time sequence of continuously performing a plurality of semiconductor process steps by a semiconductor process apparatus according to an embodiment of the present disclosure.

FIG. 11 illustrates a schematic flowchart of a power adjustment method of a power supply of an upper electrode of the semiconductor process apparatus according to an embodiment of the present disclosure.

FIG. 12 illustrates a schematic flowchart of step 10 according to an embodiment of the present disclosure.

FIG. 13 illustrates a schematic flowchart of step 11 according to an embodiment of the present disclosure.

FIG. 14 illustrates a schematic principle block diagram of a semiconductor process apparatus according to an embodiment of the present disclosure.

### DETAILED DESCRIPTION OF THE EMBODIMENTS

Embodiments of the present disclosure are described in detail in connection with the accompanying drawings. It should be understood that the specific embodiments described here are merely used for illustrating and explaining the present disclosure and are not intended to limit the scope of the present disclosure.

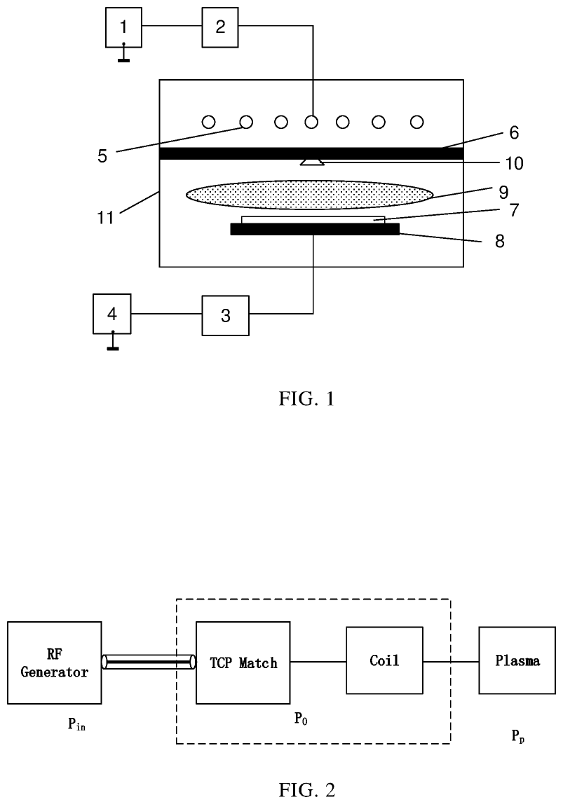

FIG. 1 shows a structure of an existing semiconductor process apparatus. An electrostatic chuck 8 is arranged in a reaction chamber 11 and configured to carry a wafer 7. A nozzle 10 is arranged at a dielectric window 6 (e.g., a quartz window) at a top of the reaction chamber 11. A process gas can enter the reaction chamber 11 through the nozzle 10. An upper electrode power supply can be configured to apply a radio frequency (RF) power to an inductive coupling coil 5 through a matcher 2. The inductive coupling coil 5 can be configured to couple RF energy through the dielectric window 6 into the chamber to excite the process gas in the reaction chamber 11 to generate a plasma 9 to act on the wafer 7. A bias RF generator 4 can be configured to apply RF energy to the electrostatic chuck 8 (e.g., an RF copper column located at a bottom of the electrostatic chuck) through a matcher 3 to provide an RF field to generate an RF bias voltage to form an ion acceleration sheath layer on the wafer surface to etch the wafer 7.

When the RF power provided by the upper electrode power supply 1 forms an RF current, and the RF current is applied to the inductive coupling coil 5, an induced magnetic field can be generated in the reaction chamber 11. The induced magnetic field can be time-varying to generate an annular induced electric field, which excites the process gas in the reaction chamber 11 to form the plasma. When different loaded RF powers are loaded, the state parameter such as the plasma density can change. Thus, the generated process result can change subsequently. Therefore, the overall efficiency of the upper electrode circuit can be closely related to the state consistency of the plasma and the process result.

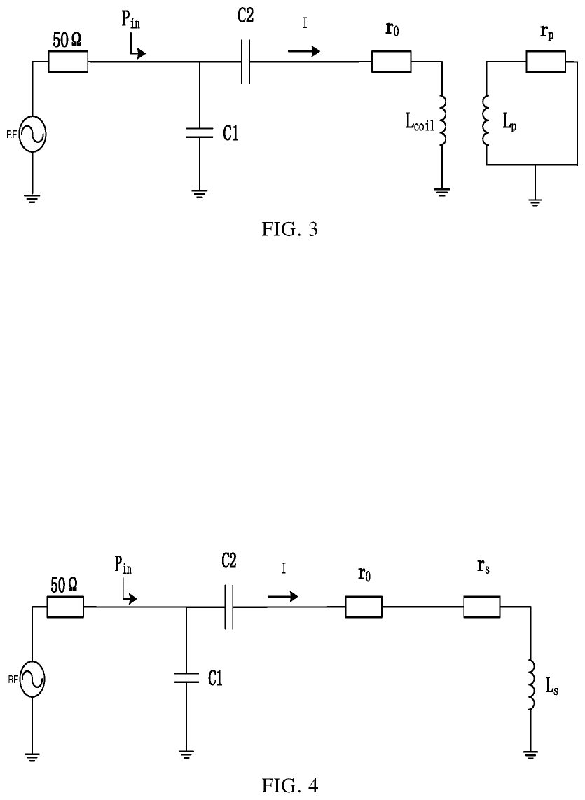

As shown in FIG. 2, the power loss of the upper electrode RF circuit of an Inductively Coupled Plasma (ICP) mainly includes of a matcher loss (TCP Match), a coil loss (Coil), a contact loss, etc. When the output power of the RF generator is Pᵢₙ, the matcher loss of the circuit, the coil loss, and the contact loss can be considered as a whole P₀. The power utilized by the plasma can be Pₚ=Pᵢₙ−P₀. The efficiency of the upper electrode RF circuit can be set as η, then η=Pₚ/Pᵢₙ. The equivalent circuit of the upper electrode RF circuit is shown in FIG. 3. C1 and C2 are variable capacitors in the upper matcher (i.e., matcher 2 in FIG. 1). A loss resistance of the matcher, a loss resistance of the coil, and a circuit contact resistance can be regarded as an equivalent resistance r₀. L_{coil} denotes the coil inductance, rₚ is the real part of the impedance of the plasma generated under the transformer model of inductive coupling, Lₚ is the imaginary part of the equivalent inductance. After impedance equivalent transformation is performed on the backend transformer model, the real part of the backend overall equivalent impedance rₛ and the imaginary part of the equivalent inductance Lₛ are obtained. The equivalent circuit is shown in FIG. 4.

Since the matchers, the coils, and the mounting contact resistances of the upper electrode RF circuits related to the power loss are different between different apparatuses of the same model number (same structure), that is, the overall hardware loss resistances r₀ are different, when the output power of the RF generators are the same, the losses of the upper electrode RF circuits can be different. Thus, the power reached to the plasma can be different, and the state parameter such as the generated plasma density can be different, which eventually affects the process result consistency. Therefore, by controlling the consistency of the RF power output by the generator, the consistency of the plasma parameter and the process repeatability can be difficult to guarantee. Process matching of the plurality of apparatuses (improve the reliability) can be more difficult.

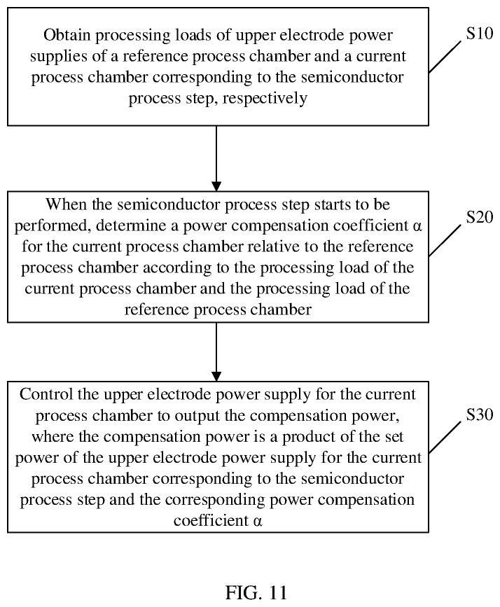

To address the above technical problems, as an aspect of the present disclosure, a power adjustment method of the upper electrode power supply of the semiconductor process apparatus is provided, as shown in FIG. 11. The method includes the following processes.

At S10, processing loads of upper electrode power supplies of a reference process chamber and a current process chamber corresponding to the semiconductor process step are obtained respectively.

The reference process chamber can be specified from the plurality of process chambers with the same structure. The current process chamber can be any other process chamber performing the semiconductor process step except for the reference process chamber. In addition, the plurality of process chambers with the same structure can belong to the same semiconductor process apparatus or different semiconductor process apparatuses.

At S20, when the semiconductor process step starts to be performed, a power compensation coefficient α for the current process chamber relative to the reference process chamber is determined according to the processing load of the current process chamber and the processing load of the reference process chamber.

At S30, the upper electrode power supply for the current process chamber is controlled to output the compensation power, where the compensation power is a product of the set power of the upper electrode power supply for the current process chamber corresponding to the semiconductor process step and the corresponding power compensation coefficient α.

In some embodiments, the above step S20 can specifically include:

calculating a ratio of the processing load of the current process chamber to the processing load of the reference process chamber, and using the ratio as the power compensation coefficient α.

However, embodiments of the present disclosure are not limited to this. In practical applications, the power compensation coefficient α can also be determined using other calculation methods according to the processing load of the current process chamber and the processing load of the reference process chamber, which is not limited in embodiments of the present disclosure.

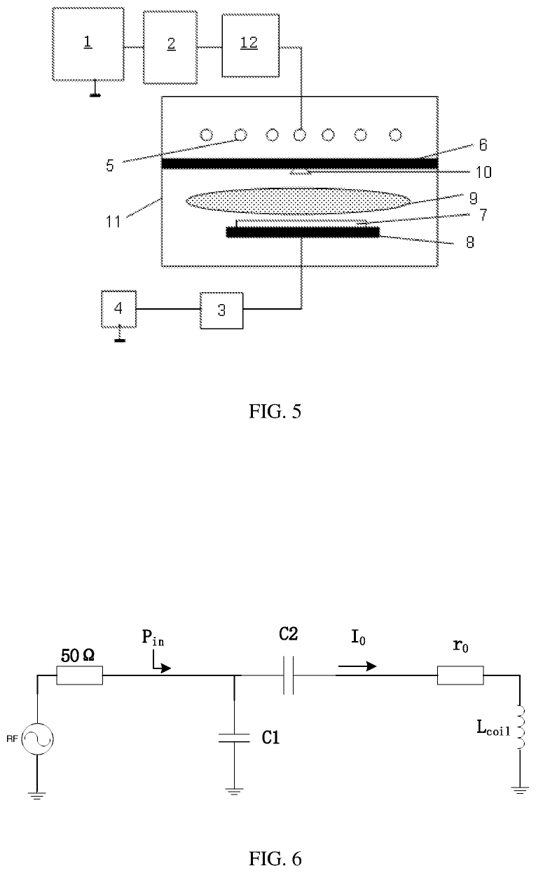

Embodiments of the present disclosure do not limit the upper electrode circuit structure of the process chamber. For example, optionally, as shown in FIG. 5 and FIG. 6, an upper electrode circuit is also arranged on the process chamber. The upper electrode power supply 1 can be configured to output electrical energy to the corresponding process chamber 11 through the corresponding upper electrode circuit (including but not limited to the matcher 2, a current detection device 12, the RF coil 5, and cables connecting the corresponding members). For each process chamber, the load carried by the upper electrode power supply when performing the semiconductor process step can include a circuit load of the upper electrode circuit (i.e., the circuit load r₀ shown in FIG. 4) and the load of the plasma generated in the process chamber 11 (i.e., the plasma load rₛ shown in FIG. 4). Through the calculation, the load Pₚ eventually applied to the plasma satisfies the following equation:

Pₚ=Pᵢₙ×[rₛ/(rₛ+r₀)]

where Pᵢₙ denotes the output power of the RF generator 1, rₛ denotes the plasma load of the reference process chamber, and r₀ denotes the load of the upper electrode circuit.

It should be noted that whether the reference process chamber or other process chambers, the circuit load r₀ above can remain unchanged when the process is performed, while the plasma load rₛ can vary with different process steps (generally ranging from 0.8Ω to 2.2Ω). However, within the same semiconductor process step, the plasma load rₛ can remain unchanged. Based on this, the circuit load r₀ can be used to reflect the upper electrode loss characteristics between different chambers and compensate for the differences in the load Pₚ applied to the plasma between other process chambers and the reference process chamber. Thus, the loads Pₚ can be the same between different chambers, thereby improving the parameter consistency of the plasma in different process chambers to further improve the process result consistency.

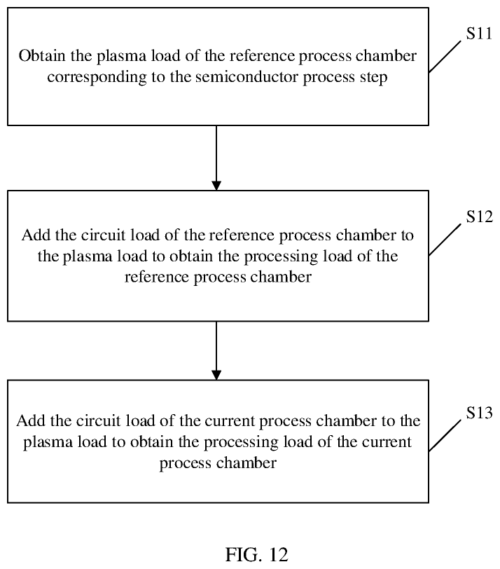

For example, before adjustment, for the same semiconductor process step, the load applied to the plasma in the reference process chamber is Pₚ₁=Pᵢₙ×[rₛ/(rₛ+r₀₁)], while the load applied to the plasma in the certain current process chamber is Pₚ₂=Pᵢₙ×[rₛ/(rₛ+r₀₂)]. The difference between Pₚ₁ and Pₚ₂ is caused by r₀₁ and r₀₂. Based on this, as shown in FIG. 12, the above step S10 specifically includes:
at S11, obtaining the plasma load rₛ of the reference process chamber corresponding to the semiconductor process step;
at S12, adding the circuit load r₀₁ of the reference process chamber to the plasma load rₛ to obtain the processing load (rₛ+r₀₁) of the reference process chamber; and
at S13, adding the circuit load r₀₂ of the current process chamber to the plasma load rₛ to obtain the processing load (rₛ+r₀₂) of the current process chamber.

In this case, the above step S20 specifically includes:

calculating the ratio of the processing load (rₛ+r₀₂) of the current process chamber to the processing load (rₛ+r₀₁) of the reference process chamber and using this ratio as the power compensation coefficient α. That is, α=(rₛ+r₀₂)/(rₛ+r₀₁). Thus, the load applied to the plasma in the current process chamber is Pₚ₂=Pᵢₙ×[rₛ/(rₛ+r₀₂)]×α=Pᵢₙ×[rₛ/(rₛ+r₀₂)]×[(rₛ+r₀₂)/(rₛ+r₀₁)], which is equal to the load Pₚ₁ applied to the plasma in the reference process chamber.

The power adjustment method of embodiments of the present disclosure can include obtaining the power compensation coefficient for the current process chamber relative to the reference process chamber according to the processing load of the upper electrode power supply of the reference process chamber and the processing load of the upper electrode power supply of the current process chamber corresponding to the semiconductor process step, and controlling the upper electrode power supply of the current process chamber to output the compensation power. The compensation power can be equal to the product of the set power of the upper electrode power supply of the current process chamber corresponding to the semiconductor process step and the corresponding power compensation coefficient. Thus, the power applied to the plasma of the current process chamber can be consistent with the reference process chamber to improve the consistency of the parameters of the plasma in different process chambers to further improve the process result consistency.

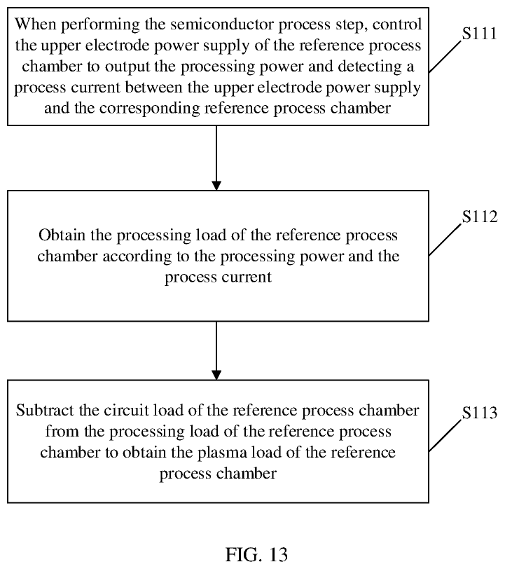

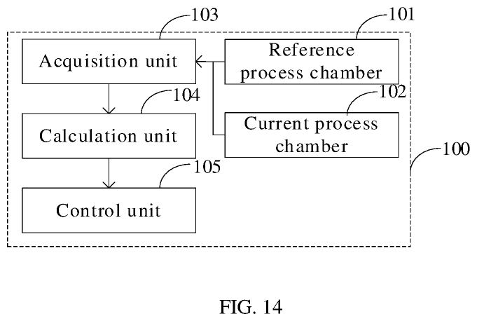

The plasma load rₛ of the reference process chamber corresponding to the semiconductor process step can be obtained in different manners. For example, as shown in FIG. 13, step S11 specifically includes:
at S111, when performing the semiconductor process step, controlling the upper electrode power supply of the reference process chamber to output the processing power P and detecting a process current I between the upper electrode power supply and the corresponding reference process chamber;
at S112, obtaining the processing load (rₛ+r₀₁) of the reference process chamber according to the processing power P and the process current I; and
at S113, subtracting the circuit load r₀₁ of the reference process chamber from the processing load (rₛ+r₀₁) of the reference process chamber to obtain the plasma load rₛ of the reference process chamber.

In embodiments of the present disclosure, the plasma load rₛ of the reference process chamber can be obtained by performing the semiconductor process detection once on the reference process chamber. That is, the processing loads of other process chambers can be obtained corresponding to the same semiconductor process step through calculation. Thus, the efficiency of obtaining the processing load can be improved to further improve the calculation efficiency of the power compensation coefficient α.

In some embodiments, step S112 specifically includes:

calculating the ratio of the square of the processing power P to the square of the process current I (P/I²) and using it as the processing load (rₛ+r₀₁).

In some embodiments, in step S12 and step S13, the circuit load r₀ of any process chamber of the reference process chamber and the current process chamber can be obtained by:
controlling the upper electrode power supply to output detection power P₀ of the process chamber and detecting the detection current I₀ between the upper electrode power supply and the process chamber, the plasma being not ignited in the process chamber under the detection power P₀; and
obtaining the circuit load r₀ of the process chamber according to the detection power P₀ and the detection current I₀ of the process chamber.

It should be noted that the detection power P₀ above is generally lower than the output power Pᵢₙ of the RF generator 1 when the semiconductor process step is performed. Thus, the detection power P₀ can be completely consumed on the upper electrode circuit without causing plasma ignition in the chamber. Thus, no plasma load is generated.

In some embodiments, obtaining the circuit load r₀ of the process chamber according to the detection power P0 and the detection current I0 of the process chamber specifically includes:

calculating the ratio of the detection power P₀ to the square of the detection current I₀ (P₀/I₀²) and using the ratio as the circuit load r₀.

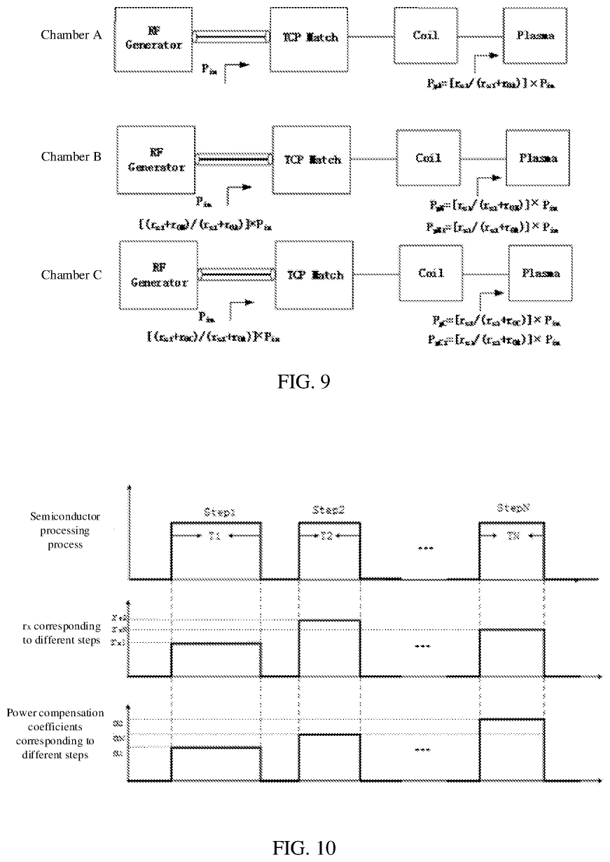

In a specific embodiment, as shown in FIG. 9, when semiconductor process step 1 is performed by using chamber A, chamber B, and chamber C, taking chamber A as the reference process chamber for example, the plasma load rₛ₁ of the reference process chamber (i.e., chamber A) corresponding to semiconductor process step 1 is obtained first. Then, the processing load (rₛ₁+r_{0A}) of the reference process chamber (i.e., chamber A), the processing load (rₛ₁+r_{0B}) of chamber B, and the processing load (rₛ₁+r_{0C}) of chamber C corresponding to semiconductor process step 1 are calculated. Subsequently, the ratios (i.e., power compensation coefficient) of the processing load of chamber B to the processing load of chamber A and the processing load of chamber C to the processing load of chamber A are obtained, respectively.

As shown in FIG. 9, for semiconductor process step 1, the power compensation coefficient of chamber B is (rₛ₁+r_{0B})/(rₛ₁+r_{0A}). The input power Pᵢₙ of chamber A is eventually applied to the plasma in chamber A with a load of P_{pA1}=[rₛ₁/(rₛ₁+r_{0A})]×Pᵢₙ. Before adjustment, the input power Pᵢₙ of chamber B is loaded to the plasma in chamber B with a load of P_{pB1}=[rₛ₁/(rₛ₁+r_{0B})]×Pᵢₙ. After adjusting the input power of chamber B according to the compensation coefficient (rₛ₁+r_{0B})/(rₛ₁+r_{0A}) to [(rₛ₁+r_{0B})/(rₛ₁+r_{0A})]×Pᵢₙ, the load applied to the plasma of chamber B is:

P_{pB1}=[rₛ₁/(rₛ₁+r_{0B})]×[(rₛ₁+r_{0B})/(rₛ₁+r_{0A})]×Pᵢₙ=[rₛ₁/(rₛ₁+r_{0A})]×Pᵢₙ

That is, the load P_{pB1} applied to the plasma of chamber B is equal to the load P_{pA1} applied to the plasma of chamber A, which improves the process result consistency between chamber B and the reference process chamber (i.e., chamber A).

Similarly, for semiconductor process step 1, the power compensation coefficient of chamber C can be (rₛ₁+r_{0C})/(rₛ₁+r_{0A}). Before the adjustment of the output power Pᵢₙ of chamber C, the load applied to the plasma in chamber C is P_{pC1}=[rₛ₁/(rₛ₁+r_{0C})]×Pᵢₙ. After adjusting the input power of chamber C to [(rₛ₁+r_{0C})/(rₛ₁+r_{0A})]×Pᵢₙ according to the compensation coefficient (rₛ₁+r_{0C})/(rₛ₁+r_{0A}), the load applied to the plasma of chamber C is:

P_{pC1}=[rₛ₁/(rₛ₁+r_{0C})]×[(rₛ₁+r_{0C})/(rₛ₁+r_{0A})]×Pᵢₙ=[rₛ₁/(rₛ₁+r_{0A})]×Pᵢₙ

That is, the load P_{pC1} applied to the plasma of chamber C can be equal to the load PpA1 applied to the plasma of chamber A, which improves the process result consistency between chamber C and the reference process chamber (i.e., chamber A).

In some optional embodiments, as shown in FIG. 10, a plurality of semiconductor process steps are provided, denoted as Step1, Step2, . . . , StepN, where N is an integer greater than 1. Process times corresponding to the number N process steps are T1, T2, . . . , TN, respectively. In this case, after performing step S11 and before performing all the semiconductor process steps, the power adjustment method of the upper electrode power supply of embodiments of the present disclosure further includes:
writing the obtained plasma loads (rₛ₁, rₛ2, . . . , I_{sN}) corresponding to the semiconductor process steps of the reference process chamber into a parameter table, as shown in Table 1-1 below; and

TABLE 1-1
Plasma Loads Corresponding to Different Process Steps

| Step | rₛ |
|---|---|
| 1 | rₛ₁ |
| 2 | rₛ₂ |
| . . . | . . . |
| N | r_{sN} |

accessing the circuit load of the reference chamber and the circuit load of the current process chamber.

Based on the above, step S20 includes:
when performing a first semiconductor process step Step1, accessing the plasma load rₛ₁ in the above parameter table of the reference process chamber corresponding to the current first semiconductor process step Step1;
performing step S12 and step S13 to obtain the processing load of the current process chamber;
determining the power compensation coefficient α1 of the current process chamber relative to the reference process chamber corresponding to the first semiconductor process step Step1 according to the processing load of the current process chamber and the processing load of the reference process chamber;
controlling the upper electrode power supply of the current process chamber to output the compensation power after being compensated by the power compensation coefficient; and
after completing the first semiconductor process step Step1, starting to perform a second semiconductor process step Step2. The power adjustment process for Step2 is the same as the power adjustment process for Step1, which is not repeated here.

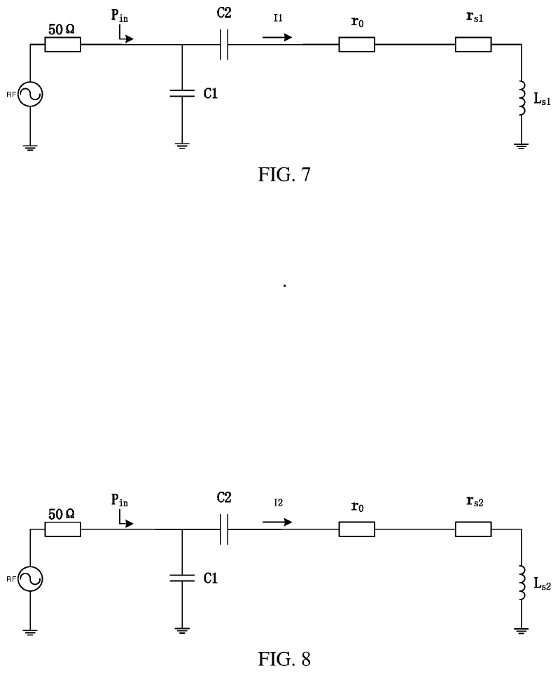

As shown in FIG. 7 and FIG. 8, when the first semiconductor process step Step1 is performed, the plasma load rₛ₁ (i.e., the real part rₛ₁ of the impedance of the process chamber) corresponding to the first semiconductor process step Step1 is obtained according to the input power Pᵢₙ (i.e., processing power P) and the process current I₁. When the second semiconductor process step Step2 is performed, the plasma load rₛ₂ (i.e., the real part rₛ₂ of the impedance of the process chamber) corresponding to the second semiconductor process step Step2 is obtained according to the input power Pᵢₙ (i.e., processing power P) and the process current I₂. As shown in FIG. 10, when N semiconductor process steps (Step1, Step2, . . . , StepN) are performed in sequence, the compensation coefficients α (α1, α2, . . . , αN) corresponding to the N process steps are quickly calculated by directly accessing the plasma loads corresponding to the N process steps, which improves the power adjustment efficiency for the RF generator.

A second aspect of the present disclosure provides a semiconductor process apparatus. The semiconductor process apparatus can be configured to adjust the power of the upper electrode power supply of at least one process chamber in the power adjustment method of the upper electrode power supply of embodiments of the present disclosure. As shown in FIG. 14, the semiconductor process apparatus 100 includes a plurality of process chambers. Any one process chamber of the plurality of process chambers is used as a reference process chamber 101. A current process chamber of the other process chambers that performs the semiconductor process step is used as a current process chamber 102 (FIG. 14 only shows one current process chamber 102).

The present disclosure does not specifically limit the output frequency of the upper electrode power supply for any process chamber. For example, optionally, the output frequency of the upper electrode power supply can be 13.56 MHz.

The semiconductor process apparatus 100 of embodiments of the present disclosure includes:
an acquisition unit 103 configured to obtain the processing load of the upper electrode power supply for the reference process chamber 101 and the processing load of the upper electrode power supply for the current process chamber 102 corresponding to the semiconductor process steps;
a calculation unit 104 configured to determine the power compensation coefficient of the current process chamber 102 relative to the reference process chamber 101 corresponding to the semiconductor process step according to the processing load of the current process chamber 102 and the processing load of the reference process chamber 101; and
a control unit 105 configured to control the upper electrode power supply to output the compensation power of the current process chamber 102 when the semiconductor process step is performed, the compensation power being a product of the set power of the upper electrode power supply of the current process chamber 102 corresponding to the semiconductor process step and the corresponding power compensation coefficient.

In some embodiments, as shown in FIG. 5, the acquisition unit 103 includes a plurality of current detection devices 12. A number of the plurality of current detection devices 12 is the same as the number of the process chambers (including the reference process chamber 101 and all other process chambers). The current detection devices 12 are arranged between the upper electrode power supplies and the corresponding process chambers in a one-to-one correspondence. The current detection device 12 can be configured to obtain the process current and/or the detection current between the corresponding upper electrode power supply and the corresponding process chamber. The detection current refers to the current outputted by the upper electrode power supply when the plasma ignition is not initiated in the process chamber.

The above current detection device 12 can be configured to obtain the process current between the corresponding upper electrode power supply and the corresponding process chamber. The processing load of the reference process chamber can be obtained according to the processing power and the process current to calculate the plasma load rₛ of the reference process chamber. The above current detection device 12 can be configured to obtain the detection current between the corresponding upper electrode power supply and the corresponding process chamber to obtain the circuit load r₀ of the process chamber. Thus, the processing load of the upper electrode power supply of the reference process chamber and the processing load of the upper electrode power supply of the current process chamber corresponding to the semiconductor process step can be further calculated.

In some embodiments, the above calculation unit 104 and the control unit 105 can be a controller.

In summary, with the power adjustment method and the semiconductor process apparatus of embodiments of the present disclosure, the power compensation coefficient of the current process chamber relative to the reference process chamber can be obtained according to the processing load of the upper electrode power supply of the reference process chamber and the processing load of the upper electrode power supply of the current process chamber corresponding to the semiconductor process step. The upper electrode power supply of the current process chamber can be controlled to output the compensation power. The compensation power can be the product of the set power of the upper electrode power supply of the current process chamber corresponding to the semiconductor process step and the corresponding power compensation coefficient. Thus, the power applied to the plasma in the current process chamber can remain consistent with the power applied to the plasma in the reference process chamber to improve the parameter consistency of the plasma in different process chambers to further improve the process result consistency.

It should be understood that the above embodiments are merely exemplary embodiments used to explain the principles of the present disclosure. However, the present disclosure is not limited to this. Those skilled in the art can make various modifications and improvements without departing from the spirit and essence of the present disclosure. Those modifications and improvements are within the scope of the present disclosure.

1. A power adjustment method, comprising:
obtaining a processing load of an upper electrode power supply of a reference process chamber and a processing load of an upper electrode power supply of a current process chamber corresponding to a semiconductor process step;
when starting the semiconductor process step, determining a power compensation coefficient corresponding to the semiconductor process step for the current process chamber relative to the reference process chamber according to the processing load of the current process chamber and the processing load of the reference process chamber; and
controlling the upper electrode power supply of the current process chamber to output a compensation power, the compensation power being a product of a set power of the upper electrode power supply of the current process chamber corresponding to the semiconductor process step and the corresponding power compensation coefficient.

2. The method according to claim 1, wherein determining the power compensation coefficient for the current process chamber relative to the reference process chamber according to the processing load of the current process chamber and the processing load of the reference process chamber includes:
calculating a ratio between the processing load of the current process chamber and the processing load of the reference process chamber,
the ratio being the power compensation coefficient.

3. The method according to claim 1, wherein:
upper electrode circuits are arranged at the reference process chamber and the current process chamber;
an upper electrode power supply is configured to output power to a corresponding process chamber through a corresponding upper electrode circuit; and
obtaining the processing load of the upper electrode power supply of the reference process chamber and the processing load of the upper electrode power supply of the current process chamber corresponding to the semiconductor process step includes:
obtaining a plasma load of the reference process chamber corresponding to the semiconductor process step;
adding a circuit load of the reference process chamber and the plasma load to obtain the processing load of the reference process chamber; and
adding a circuit load of the current process chamber and the plasma load of the reference process chamber to obtain the processing load of the current process chamber.

4. The method according to claim 3, wherein obtaining the plasma load of the reference process chamber corresponding to the semiconductor process step includes:
when performing the semiconductor process step, controlling the upper electrode power supply of the reference process chamber to output a processing power and detecting a process current between the upper electrode power supply and the reference process chamber;
obtaining the processing load of the reference process chamber according to the processing power and the process current; and
subtracting the circuit load of the reference process chamber from the processing load of the reference process chamber to obtain the plasma load of the reference process chamber.

5. The method according to claim 4, wherein obtaining the processing load of the reference process chamber according to the processing power and the process current includes:
calculating a ratio of the processing power to square of the process current,
the ratio being the processing load.

6. The method according to claim 3, wherein obtaining the circuit load of any one of the reference process chamber and the current process chamber includes:
controlling the upper electrode power supply of the process chamber to output detection power to detect a detection current between the upper electrode power supply and the process chamber, the plasma being not ignited in the process chamber under the detection power; and
obtaining the circuit load of the process chamber according to the detection power and detection current of the process chamber.

7. The method according to claim 6, wherein obtaining the circuit load of the process chamber according to the detection power and detection current of the process chamber includes:
calculating a ratio of the detection power to square of the detection current,
the ratio being the circuit load.

8. The power control method according to claim 3,
wherein a plurality of semiconductor process steps are provided;
after obtaining the processing load of the upper electrode power supply of the reference process chamber and the processing load of the upper electrode power supply of the current process chamber corresponding to the semiconductor process step, and before starting to perform all the semiconductor process steps, the method further comprising:
writing the obtained plasma load of the reference process chamber corresponding to each semiconductor process step of the plurality of semiconductor process steps into a parameter table;
accessing the circuit load of the reference process chamber and the circuit load of the current process chamber;
when starting the semiconductor process step, determining the power compensation coefficient of the current process chamber relative to the reference process chamber corresponding to the semiconductor process step according to the processing load of the current process chamber and the processing load of the reference process chamber including:
when starting the semiconductor process steps, accessing the plasma load of the reference process chamber corresponding to a current semiconductor process step in the parameter table; and
determining the power compensation coefficient of the current process chamber relative to the reference process chamber corresponding to the current semiconductor process step according to the processing load of the current process chamber and the processing load of the reference process chamber.

9. A semiconductor process apparatus comprising:
a plurality of process chambers, the semiconductor process apparatus being configured to adjust power of upper electrode power supplies of the plurality of process chambers, any one process chamber of the plurality of process chambers being used as a reference process chamber, a process chamber of the other process chambers that performs a semiconductor process step being a current process chamber;
an acquisition unit configured to obtain a processing load of an upper electrode power supply of the reference process chamber and a processing load of an upper electrode power supply of the current process chamber corresponding to the semiconductor process step;
a calculation unit configured to, when starting the semiconductor process step, determine a power compensation coefficient corresponding to the semiconductor process step for the current process chamber relative to the reference process chamber according to the processing load of the current process chamber and the processing load of the reference process chamber; and
a control unit configured, when performing the semiconductor process step to control the upper electrode power supply of the current process chamber to output a compensation power, the compensation power being a product of a set power of the upper electrode power supply of the current process chamber corresponding to the semiconductor process step and the corresponding power compensation coefficient.

10. The apparatus according to claim 9, wherein the acquisition unit includes:
a plurality of current detection devices, a number of the plurality of current detection devices being same as a number of the process chambers, and the current detection devices being arranged between the electrode power supplies and the corresponding process chambers in a one-to-one correspondence, the current detection devices being configured to obtain a process current and/or a detection current between the corresponding upper electrode power supplies and the corresponding process chambers, and the detection current referring to a current outputted by the upper electrode power supply when the plasma is not ignited in the process chamber.

11. The apparatus according to claim 9, wherein the calculation unit is further configured to:
calculate a ratio between the processing load of the current process chamber and the processing load of the reference process chamber, the ratio being the power compensation coefficient.

12. The apparatus according to claim 9, wherein:
upper electrode circuits are arranged at the reference process chamber and the current process chamber;
an upper electrode power supply is configured to output power to a corresponding process chamber through a corresponding upper electrode circuit; and
the acquisition unit is further configured to:
obtain a plasma load of the reference process chamber corresponding to the semiconductor process step;
add a circuit load of the reference process chamber and the plasma load to obtain the processing load of the reference process chamber; and
add a circuit load of the current process chamber and the plasma load of the reference process chamber to obtain the processing load of the current process chamber.

13. The apparatus according to claim 12, wherein the acquisition unit is further configured to:
when performing the semiconductor process step, control the upper electrode power supply of the reference process chamber to output a processing power and detecting a process current between the upper electrode power supply and the reference process chamber;
obtain the processing load of the reference process chamber according to the processing power and the process current; and
subtract the circuit load of the reference process chamber from the processing load of the reference process chamber to obtain the plasma load of the reference process chamber.

14. The apparatus according to claim 13, wherein the acquisition unit is further configured to:
calculate a ratio of the processing power to square of the process current, the ratio being the processing load.

15. The apparatus according to claim 12, wherein the control unit is further configured to:
control the upper electrode power supply of the process chamber to output detection power to detect a detection current between the upper electrode power supply and the process chamber, the plasma being not ignited in the process chamber under the detection power; and
obtain the circuit load of the process chamber according to the detection power and detection current of the process chamber.

16. The apparatus according to claim 15, wherein the acquisition unit is further configured to:
calculating a ratio of the detection power to square of the detection current, the ratio being the circuit load.

17. The apparatus according to claim 12,
wherein a plurality of semiconductor process steps are provided;
the calculation unit is further configured to:
write the obtained plasma load of the reference process chamber corresponding to each semiconductor process step of the plurality of semiconductor process steps into a parameter table;
access the circuit load of the reference process chamber and the circuit load of the current process chamber;
when starting the semiconductor process step, determine the power compensation coefficient of the current process chamber relative to the reference process chamber corresponding to the semiconductor process step according to the processing load of the current process chamber and the processing load of the reference process chamber including:
when starting the semiconductor process steps, accessing the plasma load of the reference process chamber corresponding to a current semiconductor process step in the parameter table; and
determining the power compensation coefficient of the current process chamber relative to the reference process chamber corresponding to the current semiconductor process step according to the processing load of the current process chamber and the processing load of the reference process chamber.
